(19) United States
(12) Patent Application Publication
(10) Pub. No.: US 2017/0214242 A1
(43) Pub. Date: Jul. 27, 2017

(54) SYSTEM AND METHOD FOR ASSESSING SMART POWER GRID NETWORKS

(71) Applicant: North Carolina A&T State University, Greensboro, NC (US)

(72) Inventors: Pravin Vishwasrao CHOPADE, Greensboro, NC (US); Marwan U. BIKDASH, Oak Ridge, NC (US)

(21) Appl. No.: 15/321,512

(22) PCT Filed: Jul. 2, 2015
(86) PCT No.: PCT/US2015/039073

§ 371 Date: Dec. 22, 2016

Related U.S. Application Data
(60) Provisional application No. 62/020,129, filed on Jul. 2, 2014.

(51) Int. Cl. H02J 3/00; G06N 5/02; G01R 21/00; G05B 15/02

(52) U.S. Cl. CPC H02J 3/00; G05B 15/02; G06N 5/02; G01R 21/00; H02J 2003/007

(57) ABSTRACT

A method, system, and software for predicting a brownout or blackout in a smart power grid network. A network vulnerability characterization is selected among line susceptance, modified line susceptance, power traffic, and power loss. The selected characterization is analyzed based on a calculation matrix such as a pseudo-degree matrix, pseudo-Laplacian matrix, or a pseudo-adjacency matrix. A centrality score, such as degree centrality or eigenvector centrality, is determined for at least one bus in the network based on the selected network vulnerability characterization and the corresponding calculation matrix. A series of network simulations are performed based on removal of at least one bus in the network. The network simulations are specific to the selected vulnerability characterization and corresponding calculation matrix.

### RELATED APPLICATION DATA

This application claims priority under 35 U.S.C. §119(e) to U.S. Provisional Patent Application No. 62/020,129 filed Jul. 2, 2014, the disclosure of which is incorporated herein by reference in its entirety.

### STATEMENT OF GOVERNMENT RIGHTS

This invention was made with government support under HDTRA1-03-1-0010 awarded by the Defense Threat Reduction Agency. The government has certain rights in the invention.

### TECHNOLOGICAL FIELD

The present invention is directed towards smart power grid networks and, more particularly, a system and method for assessing the vulnerability of smart power grid networks.

### BACKGROUND

Smart power grid networks (SPGNs) are known in the art as modernized electrical power grids that utilize computer-based remote control and automation. The SPGNs manage electricity demand in a more sustainable, reliable, and economic manner. However, as with all types of electrical grid networks, the infrastructure of SPGNs is vulnerable to unplanned stressors and outages resulting from both intentional and unintentional acts, such as targeted attacks, weather-related events, and other emergency situations. It is desirable to have a system and method for assessing the structural and functional vulnerability of SPGNs.

### BRIEF SUMMARY

In view of the foregoing background, example implementations of the present disclosure provide a system and method for determining a centrality score for a bus in a network of buses in a smart power grid network including the steps of selecting a network vulnerability characterization for evaluating the bus, the network vulnerability characterization being selected from susceptance, modified line susceptance, power traffic, and/or power loss, and analyzing the selected network vulnerability characterization to arrive at the centrality score based on a calculation matrix of a pseudo-degree matrix, pseudo-Laplacian matrix, and/or a pseudo-adjacency matrix.

The centrality score is a degree centrality score or an eigenvector centrality score. The method further includes steps of selecting a second network vulnerability characterization for evaluating the bus, the second network vulnerability characterization being selected from susceptance, modified line susceptance, power traffic, and/or power loss, analyzing the selected second network vulnerability characterization to arrive at a second centrality score based on a calculation matrix selected from a pseudo-degree matrix, pseudo-Laplacian matrix, and/or a pseudo-adjacency matrix, and averaging the first centrality score and the second centrality score.

The line susceptance matrix factors in admittance in the buses, the modified line susceptance characterization factors in a phase difference between the buses, the power traffic characterization factors in the power transmitted between the buses, and the power loss characterization factors in the power loss between the buses. The pseudo-degree matrix includes a diagonal of non-negative integers and non-integers, and all of the remaining elements are zeros. The pseudo-adjacency matrix is symmetrical, includes a diagonal of all zeros, and comprises non-negative integers and non-integers in the remaining elements. The pseudo-Laplacian matrix is symmetrical, a sum of elements in each row is zero, and the remaining elements are integers and non-integers which may be positive and/or negative. The pseudo-degree matrix is the sum of the pseudo-Laplacian and pseudo-adjacency matrices.

In another implementation of the present invention, a method for predicting a brownout or blackout in a smart power grid network is provided, including the steps of selecting a network vulnerability characterization from line susceptance, modified line susceptance, power traffic, and/or power loss, analyzing the selected network vulnerability characterization based on a calculation matrix selected from pseudo-degree matrix, pseudo-Laplacian matrix, and/or a pseudo-adjacency matrix, determining a centrality score for at least one bus or plurality of buses in the network based on the selected network vulnerability characterization and the corresponding calculation matrix, selecting the at least one bus or plurality of buses to be removed from the network for predictive testing, and performing a series of network simulations based on removal of the at least one bus or plurality of buses from the network, the network simulations being specific to the selected vulnerability characterization and corresponding calculation matrix. The series of network simulations is analyzed to determine a plurality of thresholds for when removal of the selected bus or plurality of buses renders the network as having diminished capacity to satisfy its load or being fully unable to satisfy its load due to the centrality score of the selected bus or plurality of buses.

A system for determining a centrality score for a bus in a network of buses in a smart power grid network is provided, which includes at least one computer comprising at least one central processing unit (CPU) and at least one memory having computer readable program code portions stored therein that when executed by the at least one processing unit, cause the computer to at least process a network vulnerability characterization for evaluating the bus, the network vulnerability characterization being selected from line susceptance, modified line susceptance, power traffic, and/or power loss, and analyze the selected network vulnerability characterization to arrive at the centrality score based on a calculation matrix selected from a pseudo-degree matrix, pseudo-Laplacian matrix, and/or a pseudo-adjacency matrix.

A system for predicting a brownout or blackout in a smart power grid network is providing including at least one computer including at least one central processing unit (CPU) and at least one memory having computer readable program code portions stored therein that when executed by the at least one processing unit, cause the computer to at least select a network vulnerability characterization from line susceptance, modified line susceptance, power traffic, and/or power loss, analyze the selected network vulnerability characterization based on a calculation matrix selected from a pseudo-degree matrix, pseudo-Laplacian matrix, and/or a pseudo-adjacency matrix, determine a centrality score for at least one bus or plurality of buses in the network based on the selected network vulnerability characterization and the corresponding calculation matrix, select the at least one bus or plurality of buses to be removed from the network for predictive testing, and perform a series of network simulations based on removal of the at least one bus or plurality of buses from the network, the network simulations being specific to the selected vulnerability characterization and corresponding calculation matrix.

A computer-readable storage medium is provided for determining a centrality score for a bus in a network of buses in a smart power grid network, the computer-readable storage medium being non-transitory and having computer readable program code portions stored therein that, in response to execution by one or more central processing units (CPUs) and or more additional CPUs, cause a computer system to at least process a network vulnerability characterization for evaluating the bus, the network vulnerability characterization being selected from line susceptance, modified line susceptance, power traffic, and/or power loss, and analyze the selected network vulnerability characterization to arrive at the centrality score based on a calculation matrix selected from a pseudo-degree matrix, pseudo-Laplacian matrix, and/or a pseudo-adjacency matrix.

In a further implementation of the present invention, a computer-readable storage medium for predicting a brownout or blackout in a smart power grid network is provided, the computer-readable storage medium being non-transitory and having computer readable program code portions stored therein that, in response to execution by one or more central processing units (CPUs) and or more additional CPUs, cause a computer system to select a network vulnerability characterization selected from line susceptance, modified line susceptance, power traffic, and/or power loss, analyze the selected network vulnerability characterization based on a calculation matrix selected from a pseudo-degree matrix, pseudo-Laplacian matrix, and/or a pseudo-adjacency matrix, determine a centrality score for at least one bus or plurality of buses in the network based on the selected network vulnerability characterization and the corresponding calculation matrix, select the at least one bus or plurality of buses to be removed from the network for predictive testing, and perform a series of network simulations based on removal of the at least one bus or plurality of buses from the network, the network simulations being specific to the selected vulnerability characterization and corresponding calculation matrix.

### DETAILED DESCRIPTION

Some implementations of the present disclosure will now be described more fully hereinafter. Various implementations of the disclosure may be embodied in many different forms and should not be construed as limited to the implementations set forth herein; rather, these example implementations are provided so that this disclosure will be thorough and complete, and will fully convey the scope of the disclosure to those skilled in the art. For example, unless otherwise indicated, reference something as being a first, second or the like should not be construed to imply a particular order.

According to example implantations of the present invention, an improved system and method is provided to predict when certain factors or scenarios will cause network brownouts (power failures that affect customers in a non-insignificant manner) and blackouts (power failures that result in a majority of customers lowing power).

SPGNs are comprised of a network of interconnected buses, which are conductors at which several transmission lines are connected. Unlike prior art methods that attempt to analyze SPGN vulnerability based on simple bus analysis, such as whether the bus is operable or not, the present invention takes into account the electrical properties of the buses in the SPGN and the corresponding degree of importance of such buses in the network. In other words, the present invention determines the importance of each bus relative to the other buses in the SPGN based on each bus's electrical properties. Such properties may include admittance, capacitance, inductance, and resistance, all of which affect a bus's voltage and the power flow through it. After determining the relative importance of the buses in the SPGN, the present invention may be used to obtain assessments and models on the SPGN to determine the overall vulnerability of the network, as explained in more detail below.

The present invention contemplates derivation of both degree centrality scores and eigenvector centrality scores for the buses in a SPGN. Centrality measures are used in network analysis to rank the relative importance of vertices in a graph. The degree centrality score characterizes the centrality of a bus in terms of its connectivity to the rest of the network and reflects the opportunity for such bus to exert influence over the rest of the network or to be exposed to whatever is flowing through the network, such as disturbances, power or traffic flows, or viruses. The eigenvector centrality score characterizes the vulnerability of a bus in terms of the centrality score of all adjacent busses, wherein scores are assigned to all buses in the network based on the principle that connections to high-scoring buses contribute more to the score of the bus than equal connections to low-scoring buses.

The prior art models for determining the degree centrality and eigenvector centrality of the buses in the SPGN incorporate use of known Laplacian, adjacency and degree matrices. As shown in Table 1, in a Laplacian matrix: (a) the matrix comprises use of −1, 0, or positive integers to define interactions between transmission lines and nodes; (b) the matrix is symmetrical; and (c) the elements of every row add up to 0. As shown in Table 2, in an adjacency matrix of a network: (a) the matrix comprises only 0s and 1s (no other integers or fractional components thereof) to define interactions between transmission lines and nodes; (b) the matrix is symmetrical; and (c) the diagonal elements of the matrix are all 0s. The degree matrix is the sum of the Laplacian matrix and adjacency matrix. As shown in Table 3, it is a diagonal matrix consisting of all 0s except on the diagonal, which is comprised of integer numbers such as 1, 2, 4, 7 etc. A diagonal element counts the total number of inter-bus transmission lines connected to the corresponding bus.

TABLE 1
Laplacian Matrix

| | | | | |
|---|---|---|---|---|
| 2 | −1 | 0 | 0 | −1 |
| −1 | 4 | −1 | −1 | −1 |
| 0 | −1 | 2 | −1 | 0 |
| 0 | −1 | −1 | 3 | −1 |
| −1 | −1 | 0 | −1 | 3 |

TABLE 2
Adjacency Matrix

| | | | | |
|---|---|---|---|---|
| 0 | 1 | 0 | 0 | 1 |
| 1 | 0 | 1 | 1 | 1 |
| 0 | 1 | 0 | 1 | 0 |
| 0 | 1 | 1 | 0 | 1 |
| 1 | 1 | 0 | 1 | 0 |

TABLE 3
Degree Matrix

| | | | | |
|---|---|---|---|---|
| 2 | 0 | 0 | 0 | 0 |
| 0 | 4 | 0 | 0 | 0 |
| 0 | 0 | 2 | 0 | 0 |
| 0 | 0 | 0 | 3 | 0 |
| 0 | 0 | 0 | 0 | 3 |

Unlike the above-described prior art methods for deriving centrality scores, the present invention derives the degree centrality and eigenvector centrality scores by factoring in the electrical properties of the buses (and the feeder lines related thereto). This is achieved with novel modifications to the typical Laplacian, adjacency, and degree matrices, referred to herein as pseudo-Laplacian, pseudo-adjacency and pseudo-degree matrices, respectively. In the pseudo-Laplacian matrix in accordance with the present invention, the matrix is symmetrical and the elements of every row add up to 0, as in the typical Laplacian matrix. However, as shown in Table 4, in the pseudo-Laplacian matrix the elements are not necessarily defined by integers. Rather, the elements may be defined by values comprised of real elements such as −0.5627, −1, −2, −3, 0, 3, 4.2778, 5, etc. By adapting the matrix to also incorporate non-integers, the electrical properties of the buses may be considered. For example, a bus having stronger connection in view of its capacitance, inductance, and resistance may be defined by a −0.5 whereas a bus having a slightly weaker connection may be defined by a −0.2.

TABLE 4
Pseudo-Laplacian Matrix

| | | | | |
|---|---|---|---|---|
| 19.4471 | −15.2121 | 0 | 0 | −4.2350 |
| −15.2121 | 30.2721 | −4.7503 | −5.1158 | −5.1939 |
| 0 | −4.7503 | 9.8224 | −5.0721 | 0 |
| 0 | −5.1158 | −5.0721 | 31.7398 | −21.5519 |
| −4.2350 | −5.1939 | 0 | −21.5519 | 30.9808 |

In the pseudo-adjacency matrix, the matrix is symmetrical and the diagonal elements of the matrix are all 0s, as in a typical adjacency matrix. However, as shown in Table 5, in the pseudo-adjacency matrix, the elements are not necessarily just 0s or 1s. Rather, the elements are real and non-negative such as 0, 0.5627, 5.6317, 15.6467 etc. Its maximum by eigenvalue has an eigenvector whose elements are fractional components between 0 and 1, such as 0, 0.2. 0.5, 0.6, and 1.

TABLE 5
Pseudo-Adjacency Matrix

| | | | | |
|---|---|---|---|---|
| 0 | 15.2121 | 0 | 0 | 4.2350 |
| 15.2121 | 0 | 4.7503 | 5.1158 | 5.1939 |
| 0 | 4.7503 | 0 | 5.0721 | 0 |
| 0 | 5.1158 | 5.0721 | 0 | 21.5519 |
| 4.2350 | 5.1939 | 0 | 21.5519 | 0 |

As shown in Table 6, the pseudo-degree matrix consists of non-negative real numbers on the diagonal terms such as 21.2784, 30.7731, 7.1429, 1.8171 etc. A higher degree value typically means a bus has stronger connection, as in when the pseudo-Laplacian is based on the power-traffic characterization, as described in more detail below. It holds the same relationship, i.e., it is the sum of the pseudo-Laplacian and pseudo-adjacency matrices.

TABLE 6
Pseudo-Degree Matrix

| | | | | |
|---|---|---|---|---|
| 19.4471 | 0 | 0 | 0 | 0 |
| 0 | 30.2721 | 0 | 0 | 0 |
| 0 | 0 | 9.8224 | 0 | 0 |
| 0 | 0 | 0 | 31.7398 | 0 |
| 0 | 0 | 0 | 0 | 30.9808 |

In the present invention, the pseudo-Laplacian, pseudo-adjacency and pseudo-degree matrices are computed based on four vulnerability characterizations, i.e. line susceptance, modified line susceptance, power traffic between buses and, power loss over the lines, all of which are based on electrical properties. These four characterizations define four degree-based and four eigenvector-based centrality measures, as shown in Table 7 below.

For example, a susceptance characterization corresponds to the imaginary part of the admittance of the transmission lines connecting two buses, and, unlike the power traffic and power loss characterizations described below, the susceptance characterization is independent of the state. Thus, the susceptance-based pseudo-degree matrix gives sum of all the susceptances connected to particular bus. The susceptance based pseudo-adjacency matrix gives susceptance of lines connecting pairs of buses. A modified line susceptance characterization, on the other hand, factors in the phase difference between the buses, and is obtained under less stringent conditions. A power traffic characterization and a power loss characterization use real data from known IEEE (Institute of Electrical and Electronics Engineers) models to compute the power transmitted or lost, respectively, between the buses (nodes) of the SPGN. Power flow between buses is calculated using known Newton-Raphson load flow analysis.

The weighted values resulting from the vulnerability characterizations are computed in the pseudo-Laplacian or pseudo-adjacency or pseudo-degree matrices using known methods for scoring Laplacian, adjacency and degree matrices that are specific to the vulnerability characterization that was used. The results are degree centrality and eigenvector centrality scores for each bus wherein the respective sums of the centrality scores for all the buses in the network is 1 (meaning 100%).

It should be understood that more than one vulnerability characterization can be used to assess a network. For example, the line susceptance characterization may help with analyzing structural vulnerability of the network whereas modified line susceptance, power traffic, and power loss characterizations may assist with analyzing functional vulnerability of the network. In one example implementation, the pseudo-Laplacian, pseudo-adjacency or pseudo-degree matrices are separately computed for each vulnerability characterization and then the centrality scores are averaged. The term “average” as used herein includes raw averages and/or weighted averages as determined by one of ordinary skill in the art.

Once each bus has been assigned a centrality score, the buses can be ranked by order of importance. For example, a bus carrying 50% of the load is ranked higher than a bus carrying 20% of the load. The centrality distributions are used to identify nodes or branches in the systems which are of important in terms of system vulnerability. Several centrality measures may be computed and compared under different attack scenarios so that their ability to predict SPGN brownout or blackout can be assessed. The topological and susceptance-based centralities are important from the point of structural vulnerability analysis. The modified susceptance-based, power traffic and power loss centralities are important from the point of functional vulnerability analysis.

In order to assess the vulnerability of the SPGN under specific failure scenarios, in accordance with the present invention, random scenarios of centrality loss (resulting from removed buses or combinations of buses) are analyzed via a software-based truth model of the grid in question which is described using standardized IEEE models and comprised of solution methods that are accepted by the industry. Such test data may comprise real and historical data regarding power networks, typically available to the power companies. The algorithm associated with the relevant truth model is specific to the vulnerability characterization model that was used to generate the weighted values for the buses and the scoring method that was used to compute the centrality scores (e.g., pseudo-Laplacian or pseudo-adjacency or pseudo-degree). In order to provide statistical accuracy, a Monte-Carlo calculation method may be utilized to produce a large number of randomly specified simulations. By running simulations of various centrality loss combinations through the truth model, a plurality of data points are generated that reveal the correlation between the amount of centrality loss and the percentage of the SPGN's unsatisfied load (meaning, power that the SPGN is unable to supply). Such data points reveal a threshold beyond which the sum of centrality loss from removed buses generates a sudden and dramatic jump from some percentage of unsatisfied load to a 100% unsatisfied load, which is a blackout. Data and simulations have shown that, generally, about a 40 to about a 60% loss in the total network centrality score in the blackout threshold, no matter what vulnerability characterization model or scoring algorithm was used, as shown in the examples further below. Plainly stated, a SPGN may reach its blackout threshold of 50% by losing centrality from one bus having a 50% centrality score or by losing three buses whose centrality scores total 50%. Thus, the method of the present invention reveals what combinations of lost buses will produce the most damage to the network in terms of causing blackout. The blackout threshold for any SPGN is specific to the vulnerability characterization model and the scoring model that was used to compute the vulnerability characterization model. Adapting one particular vulnerability characteristic and one particular scoring algorithm may result in a sharp threshold.

Once the data points from the truth model reveal the blackout threshold for a particular network model, network operators are able to use such data in numerous ways. For example, operators can plan network upgrades by prioritizing which buses or combination of buses are most important to maintain in order to avoid brownout or blackout. Similarly, operators can plan better for targeted attacks on the network by increasing security on the most vulnerable buses or substations on the network or network stations. Additionally, in the case of a blackout, operators can determine which buses or subsets of buses should be prioritized to bring the network back out of a state of blackout. All of this prioritization and planning is made possible by determining the centrality score of the buses in the network based on their electrical properties and the threshold when a loss of centrality will cause a blackout on the network.

It should be understood that the above-described system and method are implemented via one or more software applications that instruct a computing device having a processor and memory to perform the steps described above upon input of data relating to the network buses. The one or more software applications may be remote-hosted on a backend server computer that processes data transmitted between an operator's computing device and the backend server via a communication network. The one or more software applications may also be locally housed on the operator's computing device.

Certain modifications and improvements will occur to those skilled in the art upon a reading of the foregoing summary and the more detailed description that follows. All such modifications and improvements of the present invention have been deleted herein for the sake of conciseness and readability. Numerous other aspects of embodiments, features, and advantages of the present invention will appear from the description and the accompanying tables and examples. In the description, reference is made to exemplary aspects of embodiments and/or embodiments of the invention, which can be applied individually or combined in any way with each other. Such aspects of embodiments and/or embodiments do not necessarily represent the full scope of the invention.

### EXAMPLE 1

An example of a random attack causing brownout/blackout applied to the IEEE-57 bus network using centrality based on power traffic eigenvector is considered below. Here, 20 buses were removed but no generator buses were removed. The power flow was computed using the Newton Raphson method with a maximum number of iterations of 50. One hundred Monte Carlo simulations were conducted. For every simulation, the proportion of total unsatisfied load is plotted against the total centrality score of all buses removed.

### EXAMPLE 2

A similar example of a random attack causing brownout/blackout applied to the IEEE-57 bus network using centrality based on power traffic eigenvector is considered below. In contrast with Example 1, the twenty buses removed included generator buses. The power flow was computed using the Newton Raphson method with a maximum number of iterations of 50. One hundred Monte Carlo simulations were conducted. For every simulation, the proportion of total unsatisfied load is plotted against the total centrality score of all buses removed. The proposed algorithms make sharper predictions in this case, as generator buses tend to be more important than connection buses.

### EXAMPLE 3

When the attack is by a malicious knowledgeable party, highly central and crucial buses are likely to be attacked first, hence leading to greater vulnerability to brownout/blackout. In this example, applied to the IEEE-57 bus network with centrality based on power traffic degree; between 1 and 3 buses were removed in a step-wise fashion, based on their centrality score. For instance, when 2 buses are removed at a time, buses ranked #1 and #2 (according to centrality) are first removed from the original complete network. In the next step, buses ranked #2 and #3 are removed from the original complete network; in the next step, buses ranked #3 and #4 are removed from the original complete network and so on. Analogously, when 3 buses are removed at a time, buses ranked according to centrality #1, #2 and #3 are removed in a first step, buses ranked #2, #3, and #4 are removed in a subsequent step, and so on.

For each case, the Newton Raphson method is used to compute the power flow, with a maximum number of iterations of 50. In this Example 3, when the total unsatisfied load is 1 (or 100%), a total system blackout occurs. As demonstrated here, removal of the highest centrality score buses ensures a blackout. As the buses that are removed become less central, the systemic outcome is a brownout.

### EXAMPLE 4

In this Example 4, Example 3 is repeated with a larger test case (IEEE-300 test network). A centrality-based attack on power traffic degree is conducted where between 1 and 3 buses were removed step-wise, based on their centrality score as described above in Example 3. The power traffic centrality was used and Newton-Raphson was used to compute the power flow in every case. The results of Example 4 are consistent with those of Example 3, thus demonstrating that removal of the highest centrality score buses ensures a blackout. As the buses that are removed become less central, the systemic outcome is a brownout.

1. A method for determining a centrality score for a bus in a network of buses in a smart power grid network comprising the steps of:
selecting a network vulnerability characterization for evaluating the bus, said network vulnerability characterization being selected from the group consisting of susceptance, modified line susceptance, power traffic, and power loss; and
analyzing the selected network vulnerability characterization to arrive at the centrality score based on a calculation matrix selected from the group consisting of a pseudo-degree matrix, pseudo-Laplacian matrix, and a pseudo-adjacency matrix.

2. The method of claim 1 wherein the centrality score is a degree centrality score or an eigenvector centrality score.

3. The method of claim 2 further comprising the steps of:
selecting a second network vulnerability characterization for evaluating the bus, said second network vulnerability characterization being selected from the group consisting of susceptance, modified line susceptance, power traffic, and power loss;
analyzing the selected second network vulnerability characterization to arrive at a second centrality score based on a calculation matrix selected from the group consisting of a pseudo-degree matrix, pseudo-Laplacian matrix, and a pseudo-adjacency matrix; and
averaging the first centrality score and the second centrality score.

4. The method of claim 1 wherein the line susceptance matrix factors in admittance in the buses.

5. The method of claim 1 wherein the modified line susceptance characterization factors in a phase difference between the buses.

6. The method of claim 1 wherein the power traffic characterization factors in the power transmitted between the buses.

7. The method of claim 1 wherein the power loss characterization factors in the power loss between the buses.

8. The method of claim 1 wherein the pseudo-degree matrix comprises a diagonal of non-negative integers and non-integers, and all of the remaining elements are zeros.

9. The method of claim 1 wherein the pseudo-adjacency matrix is symmetrical, comprises a diagonal of all zeros, and comprises non-negative integers and non-integers in the remaining elements.

10. The method of claim 1 wherein the pseudo-Laplacian matrix is symmetrical, a sum of elements in each row is zero, and the remaining elements are integers and non-integers which may be positive and/or negative.

11. The method of claim 1 wherein the pseudo-degree matrix is the sum of the pseudo-Laplacian and pseudo-adjacency matrices.

12. A method for predicting a brownout or blackout in a smart power grid network comprising the steps of:
selecting a network vulnerability characterization selected from the group consisting of line susceptance, modified line susceptance, power traffic, and power loss;
analyzing the selected network vulnerability characterization based on a calculation matrix selected from the group consisting of a pseudo-degree matrix, pseudo-Laplacian matrix, and a pseudo-adjacency matrix;
determining a centrality score for at least one bus or plurality of buses in the network based on the selected network vulnerability characterization and the corresponding calculation matrix;
selecting the at least one bus or plurality of buses to be removed from the network for predictive testing; and
performing a series of network simulations based on removal of the at least one bus or plurality of buses from the network, said network simulations being specific to the selected vulnerability characterization and corresponding calculation matrix.

13. The method of claim 12 further comprising the step of analyzing the series of network simulations to determine a plurality of thresholds for when removal of the selected bus or plurality of buses renders the network as having diminished capacity to satisfy its load or being fully unable to satisfy its load due to the centrality score of the selected bus or plurality of buses.

14. (canceled)

15. A system for predicting a brownout or blackout in a smart power grid network comprising:
at least one computer comprising at least one central processing unit (CPU) and at least one memory having computer readable program code portions stored therein that when executed by the at least one processing unit, cause the computer to at least:
select a network vulnerability characterization selected from the group consisting of line susceptance, modified line susceptance, power traffic, and power loss;
analyze the selected network vulnerability characterization based on a calculation matrix selected from the group consisting of a pseudo-degree matrix, pseudo-Laplacian matrix, and a pseudo-adjacency matrix;
determine a centrality score for at least one bus or plurality of buses in the network based on the selected network vulnerability characterization and the corresponding calculation matrix;
select the at least one bus or plurality of buses to be removed from the network for predictive testing; and
perform a series of network simulations based on removal of the at least one bus or plurality of buses from the network, said network simulations being specific to the selected vulnerability characterization and corresponding calculation matrix.

16. (canceled)

17. A computer-readable storage medium for predicting a brownout or blackout in a smart power grid network, the computer-readable storage medium being non-transitory and having computer readable program code portions stored therein that, in response to execution by one or more central processing units (CPUs) and or more additional CPUs, cause a computer system to at least:
at least one computer comprising at least one central processing unit (CPU) and at least one memory having computer readable program code portions stored therein that when executed by the at least one processing unit, cause the computer to at least
select a network vulnerability characterization selected from the group consisting of line susceptance, modified line susceptance, power traffic, and power loss;'
analyze the selected network vulnerability characterization based on a calculation matrix selected from the group consisting of a pseudo-degree matrix, pseudo-Laplacian matrix, and a pseudo-adjacency matrix;
determine a centrality score for at least one bus or plurality of buses in the network based on the selected network vulnerability characterization and the corresponding calculation matrix;
select the at least one bus or plurality of buses to be removed from the network for predictive testing; and
perform a series of network simulations based on removal of the at least one bus or plurality of buses from the network, said network simulations being specific to the selected vulnerability characterization and corresponding calculation matrix.
